(19) United States
(12) Patent Application Publication
(10) Pub. No.: US 2024/0224452 A1
(43) Pub. Date: Jul. 4, 2024

(54) COVER TO MAINTAIN ENCLOSURE PRESSURE AND HUMIDITY

(71) Applicant: Microsoft Technology Licensing, LLC, Redmond, WA (US)

(72) Inventors: Daniel T. LAU, Mountain View, CA (US); Wesley Johann STEEN, Pacifica, CA (US); Bryan LOYOLA, Redmond, WA (US); Leonardo ALDANA, Tracy, CA (US); Jason WILLIAMS, Noblesville, IN (US); Michael Neil BEERMAN, Mill Valley, CA (US); Natasha GANGJEE, Sunnyvale, CA (US); William Steven ZURBRICK, Santa Clara, CA (US); Marc Angelo CAPUL, San Francisco, CA (US)

(21) Appl. No.: 18/091,112

(22) Filed: Dec. 29, 2022

(51) Int. Cl. H05K 5/03; G02B 27/01; H05K 5/02

(52) U.S. Cl. CPC H05K 5/03; G02B 27/0176; H05K 5/0214

(57) ABSTRACT

A heads-up display includes an enclosure that includes electronics to operate the heads-up display and a visor attached to the enclosure. The heads-up display further includes a screen attached to the visor and the enclosure; and a cover assembly that is secured to the enclosure. The cover assembly includes a cap that seals the enclosure and includes at least opening; a hydrophobic membrane that prevents moisture from entering the enclosure through the at least one opening while permitting air to enter and exit the enclosure through the opening in the cap. An insert is secured to the cap and a valve is secured to the insert. The valve includes an inlet valve secured to the insert and an outlet valve secured to the insert such that the inlet valve allows air to flow into the enclosure and the outlet valve allows air to flow out of the enclosure.

### TECHNICAL FIELD

Embodiments described herein generally relate to cover assemblies for enclosures that house electronics.

### BACKGROUND

Removable cover assemblies for enclosures that include electronics typically accommodate a moisture absorbing desiccant that is exposed to the interior of the enclosure. Existing cover assemblies are not able to provide a moisture barrier, maintain humidity control, and adequately adapt to pressure changes within the enclosure when the enclosure is exposed to harsh environments such as extreme heat, extreme cold and high elevations.

### BRIEF DESCRIPTION OF THE DRAWINGS

FIG. 1 shows a perspective view of an example heads-up display.

FIG. 2 shows a perspective view of an example cover assembly.

FIG. 3 shows a sectioned perspective view of the cover assembly illustrated in FIG. 2.

FIG. 4A shows a section view of the cover assembly shown in shown in FIG. 2-3 with air passing into the cover assembly.

FIG. 4B shows a section view of the example assembly shown in shown in FIG. 4A with no air passing through the cover assembly because there is pressure equilibrium on both sides of the cover assembly.

FIG. 4C shows a section view of the cover assembly in shown in FIGS. 4A-4B with air exiting the cover assembly.

FIG. 5 shows another sectioned perspective view of the cover assembly illustrated in FIGS. 2-3.

FIG. 6 shows an exploded perspective view of the cover assembly illustrated in FIGS. 2-5 with a barrier removed from top of the cap.

FIG. 7 shows another exploded perspective view of the cover assembly illustrated in FIGS. 2-6 with a barrier included at top of the cap.

FIG. 8 shows a sectioned perspective view of an example insert that is used in the cover assembly shown in FIGS. 2-7.

FIG. 9 shows a perspective view of the example insert that is shown in FIG. 8.

FIG. 10 shows a bottom view of the example insert that is shown in FIGS. 8-9.

FIG. 11 shows a top view of the example insert that is shown in FIGS. 8-10.

FIG. 12 shows a perspective view of another example cover assembly.

FIG. 13 shows another exploded perspective view of the cover assembly illustrated in FIG. 12.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Orientation terminology, such as “horizontal,” as used in this application is defined with respect to a plane parallel to the conventional plane or surface of a wafer or substrate, regardless of the orientation of the wafer or substrate. The term “vertical” refers to a direction perpendicular to the horizontal as defined above. Prepositions, such as “on,” “side” (as in “sidewall”), “higher,” “lower,” “over,” and “under” are defined with respect to the conventional plane or surface being on the top surface of the wafer or substrate, regardless of the orientation of the wafer or substrate.

One of the concerns with existing cover assemblies is that they are unable to maintain a pressure equilibrium between the inside of an enclosure that includes electronics and the pressure of the ambient environment where the enclosure is located. Maintaining the pressure equilibrium is even more problematic when the humidity within the enclosure needs to be maintained below a particular level in order to protect the electronics within the enclosure. The pressure differential that exists, especially in harsh environments, can cause the enclosure to undesirably bulge or contract depending on the material of the enclosure.

The cover assemblies described herein are well suited to maintain a pressure equilibrium between the inside of an enclosure that includes electronics and the pressure of the ambient environment where the enclosure is located. The cover assemblies provide a solution to an enclosure bulging or contracting problem that may occur when the enclosure is operated and/or stored in harsh environments (e.g., high temperature, low temperature or high elevation).

In addition, the configuration and arrangement of the cover assemblies described herein prevent water ingress into the enclosure as well as provide volumetric air flow control into/out of the enclosure in order equalize the pressure between the inside of the enclosure and the outside of the enclosure. The cover assemblies also provide a sealed access port for easily replacing or inserting an internal desiccant pack that controls the humidity within the enclosure.

If the pressure inside the enclosure is greater than the ambient environment, then the cover assembly vents air from the enclosure to the ambient environment. If the pressure inside the enclosure is less than the ambient environment, then the cover assembly vents air from the ambient environment to the enclosure.

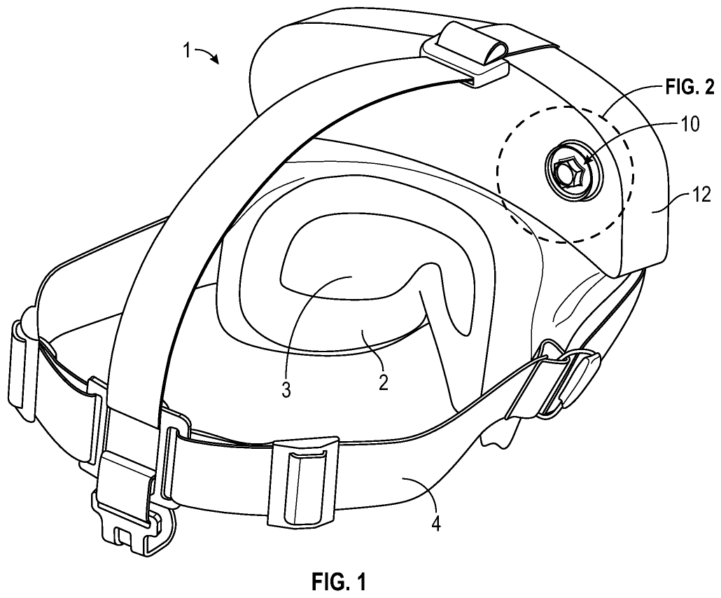

FIG. 1 shows an example heads-up display 1 that is configured to be worn on a user's head. The heads-up display 1 includes an enclosure 12 that includes electronics to operate the heads-up display 1 and a visor 2 attached to the enclosure 12. The visor 2 is configured to engage the user's face.

A screen 3 is attached to the visor 2 and the enclosure 12 for displaying information to the user. The type of screen 3 will depend in part on type of heads-up display 1 as well as the type of information that needs to be displayed to a user.

The heads-up display 1 further includes a cover assembly 10 that is secured to the enclosure 12. The cover assembly 1 provides a solution to an enclosure 12 bulging problem that can occur when the heads-up display 1 is exposed to harsh ambient environments. If this bulging of the enclosure 12 is large enough, or repeated enough times, the enclosure 12 and cover assembly 10 could become damaged and unable to maintain the proper environment within the enclosure 12 of the heads-up display 1. If the proper environment is not maintained within the enclosure 12, then the electronics within the enclosure 12 could become damaged in some way thereby negatively affecting the operation of the heads-up display 1.

The cover assembly 10 relieves an internal pressure build up within the enclosure 12 when the heads-up display 1 is used or stored in a high temperature environment. The cover assembly 10 relieves the internal pressure buildup within the enclosure 12 by allowing air to exit the enclosure 12. In addition, the cover assembly 10 compensates for an internal pressure deficit within the enclosure 12 when the heads-up display 1 is used or stored in a low temperature environment or at a high elevation. Maintaining a pressure balance between the interior of the enclosure 12 and ambient environment where the heads-up display 1 is located prevents unwanted deformation of the enclosure 12.

The cover assembly 10 serves as a sealed access port for replacing an internal desiccant pack within the enclosure 12. The desiccant pack (not shown) is used to maintain the humidity within the enclosure 12. The descant pack requires periodic replacement in order to adequately maintain the humidity within the enclosure 12. Excess humidity withing the enclosure 12 can damage the electronics that are located within the enclosure 12 as well fog up optical components.

The cover assembly 10 also prevents water ingress into the enclosure 12 while permitting air to flow into and out of the enclosure 12. Preventing water from entering the enclosure 12 while permitting air to flow into and out of the enclosure 12 is important to maintaining a proper environment within the enclosure 12. This proper environment takes the form of an equalized pressure and humidity maintained below a certain level within the enclosure 12.

In some forms, the heads-up display 1 further includes an adjustable strap 4 that is attached to enclosure 12 to the visor 2. The adjustable strap 4 facilitates securing the heads-up display 1 to the user's head. Various forms of an adjustable strap 4 are contemplated and will depend in part on the size and shapes of the other items that make up the heads-up display 1.

The cover assembly 10 is removably secured to the enclosure 12 by any number of methods. As an example, the cap 11 of the cover assembly 10 may be threaded to the enclosure 12 by the use of internal or external threads. As another example, the cap 11 maybe snapped into the enclosure 12. It should be noted that other forms of attachment for the cap 11 to the enclosure 12 are contemplated. It is further important to note that no matter how the cover assembly 10 is secured to the enclosure 12, the ability of the cover assembly 10 to maintain pressure equilibrium and humidity below a certain level needs to be maintained.

In an alternative form, the cover assembly 10 may be utilized in combination with an enclosure 12 that is part of an audio only electronic device (not shown). As an example, the audio only electronic device may be headphones or earbuds. In these other forms, the electronic device will have an enclosure that includes electronics where the pressure and humidity within the enclosure needs to be maintained.

Examples of other electronic devices include, but are not limited to, personal computers, tablet computers, mobile telephones, game devices, digital music players, etc. In another example, the cover assembly 10 may be used in an electronic device that includes a data processing system having a system bus that couples the heads-up display 1 to other electronic devices.

Alternative forms of the cover assembly 10 are described below relative to the remaining FIGS.

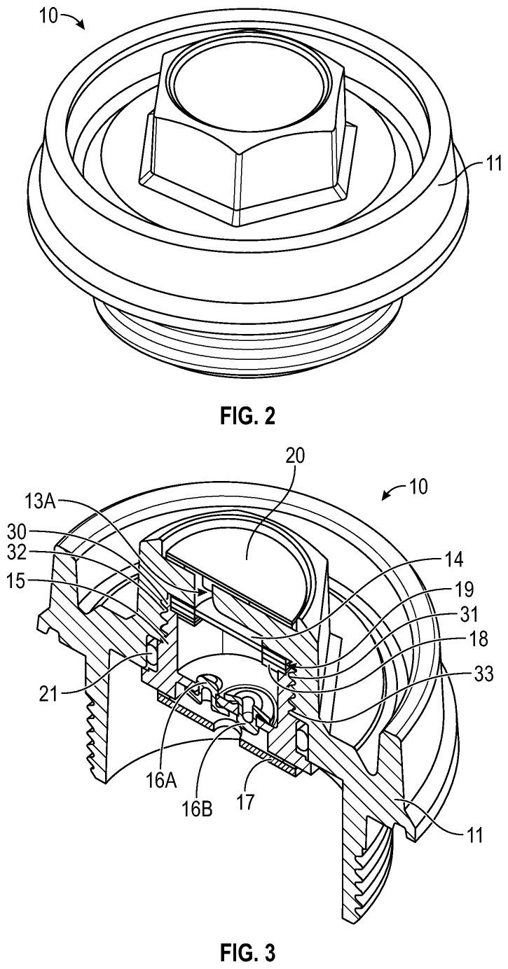

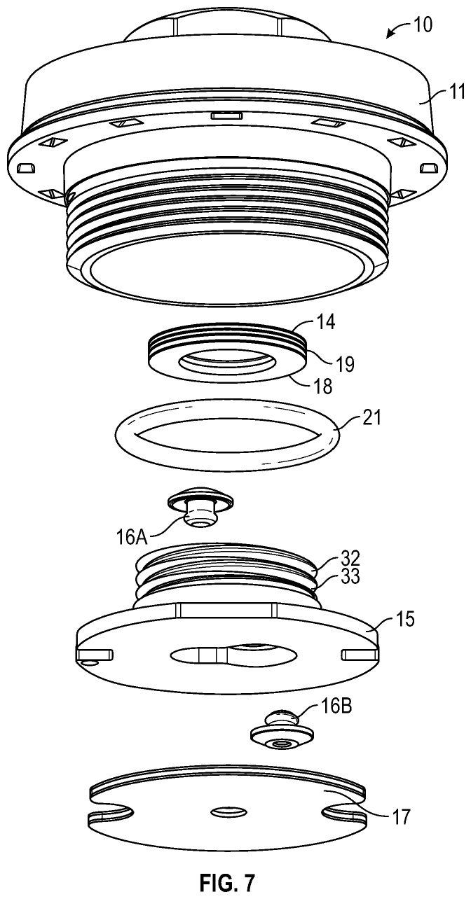

FIGS. 2-7 show various views of a cover assembly 10. The cover assembly 10 includes a cap 11 that seals the enclosure 12 (from FIG. 1) and includes at least one opening 13A to permit air to flow into and out of the enclosure 12. The shape of the cap 11 and material that is used for the cap 11 will depend in part on the configuration and materials that are used for the other components that form the cover assembly 10.

A membrane 14 prevents water from entering the enclosure 12 through the at least one opening 13A in the cap 11 while permitting air A to enter and exit the enclosure 12 through the at least one opening 13A in the cap 11. In the illustrated example form, the membrane 14 is a hydrophobic membrane that permits air A to enter and exit the enclosure 12 while preventing moisture from entering the enclosure 12. The hydrophobic membrane 14 is shown as being disc-shaped with an outer portion being configured to engage other components in the cover assembly 10 and an inner portion that permits air A to enter and exit the enclosure 12 yet still prevents moisture from entering the enclosure 12.

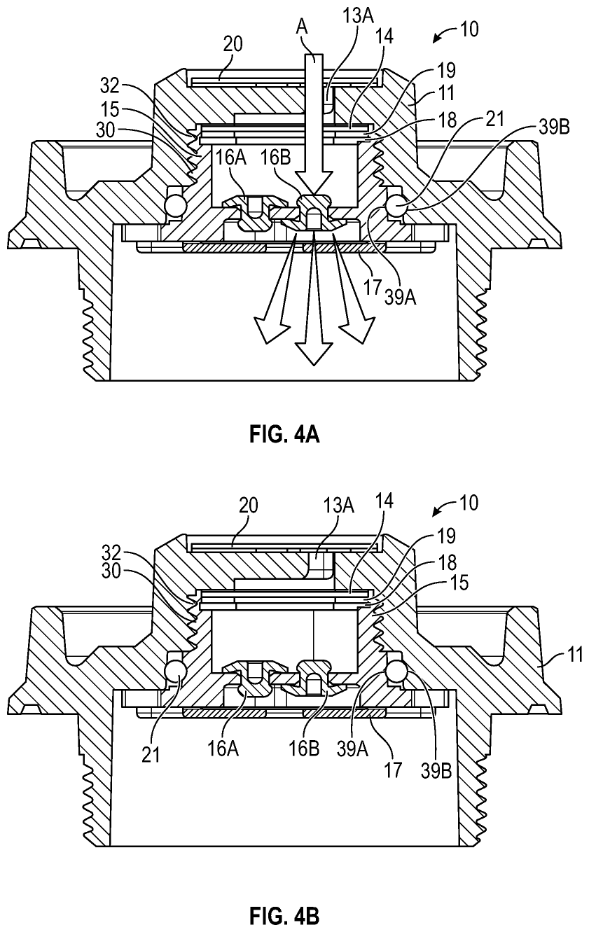

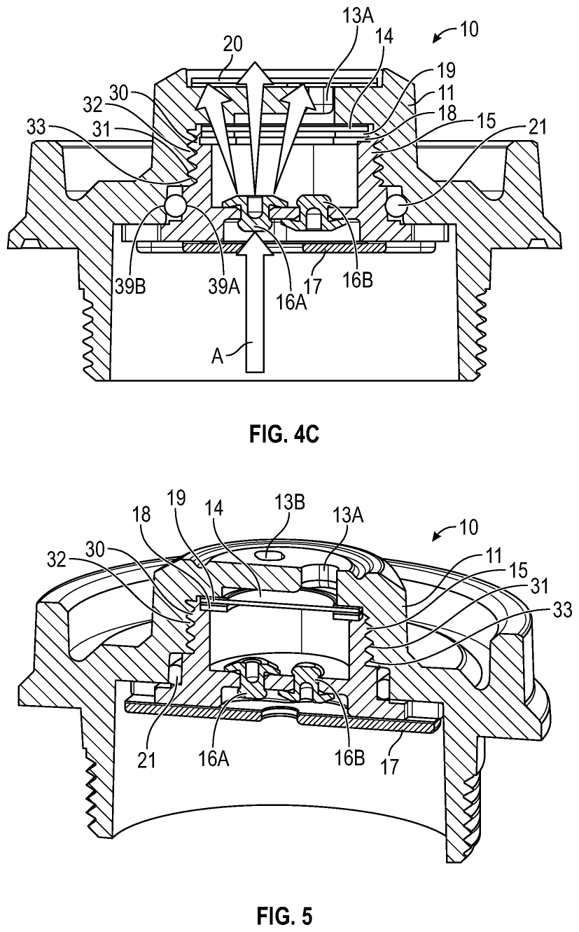

As shown in FIGS. 3-7, insert 15 is secured to the cap 11 and a valve 16A, 16B is secured to the insert 15. The valve 16A, 16B allows air A to flow into the enclosure 12 and flow out of the enclosure 12. In the illustrated example form, the valve 16A, 16B includes an inlet valve 16A that is secured to the insert 15 and an outlet valve 16B that is secured to the insert 15 such that the inlet valve 16A allows air A to flow into the enclosure 12 (FIG. 4A) and the outlet valve 16B allows air A to flow out of the enclosure 12 (FIG. 4C). Other forms are contemplated where there are more than one inlet valve 16A and more than one outlet valve 16B.

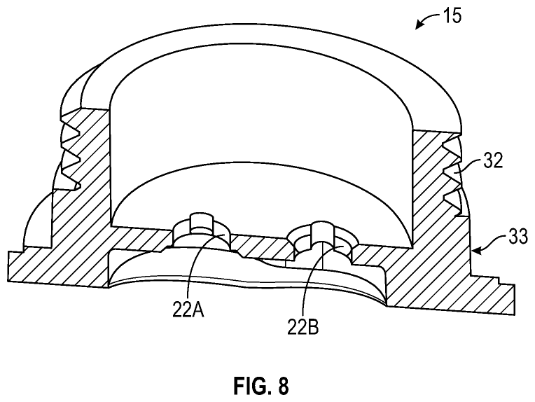

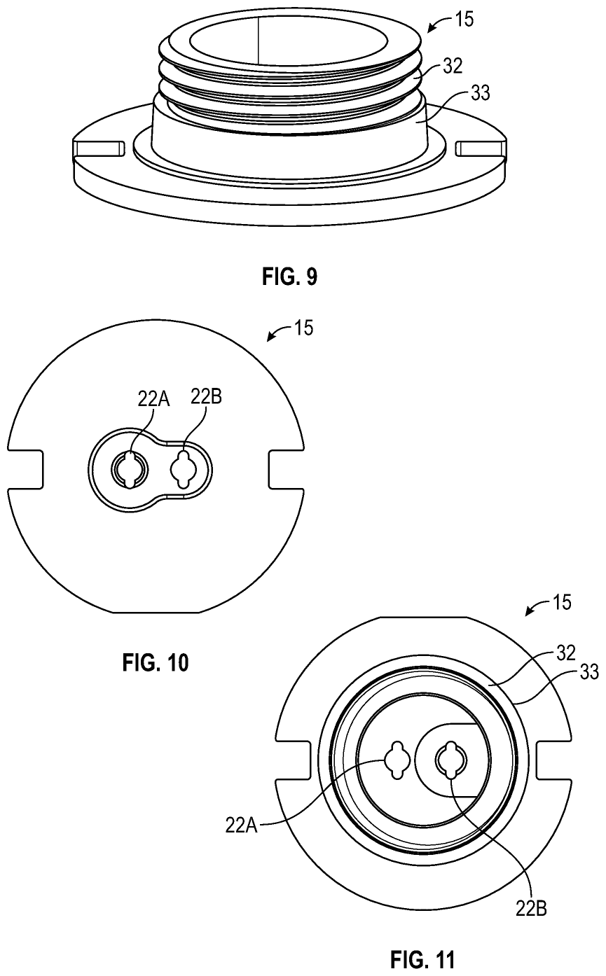

As also shown in FIGS. 8-11, the example insert 15 that is included in the cover assembly 10 includes openings 22A, 22B. The openings 22A, 22B are configured receive the inlet valve 16A and the outlet valve 16B. The size and shape of the openings 22A, 22B will depend on the type of valve(s) 16A, 16B that included in the cover assembly 10.

In the illustrated example forms, the inlet valve 16A and the outlet valve 16B are umbrella valves. It should be noted that other forms are contemplated where other types of valves are used to exchange air into and out of the enclosure 12. Umbrella valves have proven effective when used in the cover assembly 10 shown in the FIGS., but other types of valves may also be effective especially when the shape and configuration of the rest of the cover assembly 10 is modified.

It should be noted that no matter what type, size and number of valves are utilized in the cover assembly 10, the valves should prevent air from entering and exiting the enclosure 12 when there is a pressure equilibrium between the pressure inside the enclosure and the ambient environment there by extending the life of the desiccant pack. The selection of a valve and/or the design of any insert that houses the valve(s) will be determined in part by the amount of pressure differential that is required in order to open the valve(s).

The cover assembly 10 is removably attached to the enclosure 12 such that when the cover assembly 10 is removed a desiccant pack (not shown) can be inserted or replaced within the enclosure 12. The desiccant pack serves to control the humidity within the enclosure 12 thereby protecting the electronics that are within the enclosure 12 from being exposed to excessive moisture. It should be noted that the cover assembly 10 may be configured to work with different sizes and types of desiccant packs.

As shown most clearly in FIGS. 3-7, the cover assembly 10 further includes a shield 17 that protects the inlet valve 16A and the outlet valve 16B. The shield 17 may also provide an engagement surface for a replaceable desiccant that could be included as part of the cover assembly 10. The size and configuration of the shield 17 will depend in part on the size of the inlet valve 16A and the outlet valve 16B: the cover assembly 10 and the enclosure 12.

The example shield 17 that is shown in the FIGS. is predominately disc-shaped in order to fit within the insert 15 and provide protection to the inlet valve 16A and the outlet valve 16B. The shape of the shield 17 will generally conform to the interior of the insert 15. Some example materials for the shield 17 include, but are not limited to, aluminum and plastic.

The cover assembly 10 may further includes a compressible spacer 19 that is compressed between the insert 15 and the membrane 14 as well as a protective spacer 18 that is between the compressible spacer 19 and the insert 15. It should be noted that the illustrated compressible spacer 19 and protective spacer 18 are example configurations for the compressible spacer 19 and the protective spacer 18.

The overall arrangement of the compressible spacer 19 and the protective spacer 18 will depend in part on the configuration of the rest of the cover assembly 10, especially the interior of the insert 15, the cap 11 and the membrane 14. Some example materials for the compressible spacer 19 include, but are not limited to, rubbers and foams. Some example materials for the protective spacer 18 include, but are not limited to, nylon, acetal, metal or other rigid materials, preferably with low surface friction.

In some forms, the cover assembly 10 further includes a barrier 20 attached to the cap 11 to prevent particulates (e.g., sand) from entering the cover assembly 10. The overall design of the barrier 20 will depend in part on the configuration of the rest of the cap 11, especially any openings in the cap 11. It should be noted that the barrier 20 will readily permit air to pass into and out of the cover assembly 10. Some example materials for the barrier 20 include, but are not limited to, polyester mesh or weave, stainless steel mesh or weave, fabric.

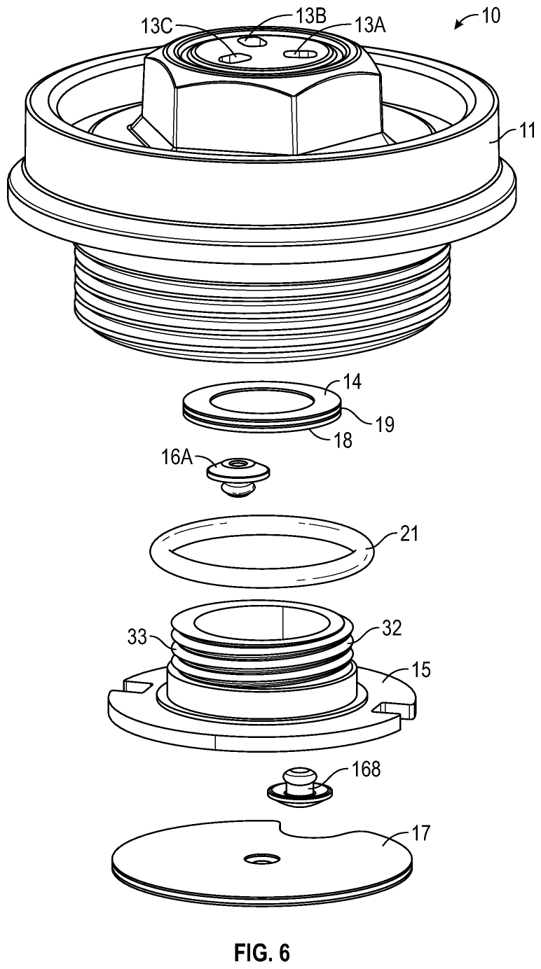

In the example form illustrated in FIG. 6, the at least one opening 13A is three openings 13A, 13B, 13C. In some forms, each of the three openings 13A, 13B, 13C has an elliptical diameter. Other arrangements, sizes and configurations for the openings 13A, 13B, 13C are contemplated. The configuration of any openings in the cap 11 needs to be able to equalize the pressure inside the enclosure 12 with the pressure of the ambient environment under a variety of harsh environmental conditions.

As shown most clearly in FIGS. 3-7, the cover assembly 10 further includes a gasket 21 between the insert 15 and the cap 11 to seal the insert 15 and the cap 11 to one another so that air only passes through the openings 13A, 13B, 13C in the cap 11. The type of gasket 21 that is utilized in the cover assembly 10 will depend on the size of the gasket and the configuration of the insert 15 and the cap 11 (among other factors). Some example materials for the gasket 21 include, but are not limited to, silicone, EPDM, glue.

The cap 11 includes internal threads 30 that are secured to external threads 32 on the insert 15. The internal threads 30 on the cap 11 are on an interior surface 31 of the cap 11, and the external threads 32 on the insert 14 are on an exterior surface 33 of the insert 15. The number and depth of the internal threads 30 and the corresponding external threads 32 will depend in part on the relative sizes of the cap 11 and the insert 15 as well as the desired degree of sealing that is required between the cap 11 and the insert 15. The use of internal threads 30 and external threads 32 promote easy assembly of the insert 15 to the cap 11.

In the example form illustrated in FIGS., the gasket 21 engages the exterior surface 33 of the insert 15 and the interior surface 31 of the cap 11 at a location adjacent to where in the internal threads 30 on the cap 11 engage the external threads 32 on the insert 15. It should be noted that the interior surface 31 of the cap 11 and the exterior surface 33 of the insert 15 could include recesses 39A, 39B that are accommodated to fit the gasket 21 (see FIGS. 4A-4C).

The configuration of such recesses 39A, 39 will depend in part on the size of the gasket 21 and the degree of sealing that is required between the cap 11 and the insert 15. The use of recesses 39A, 39B may make it easier to properly insert the gasket 21 within the cover assembly 10.

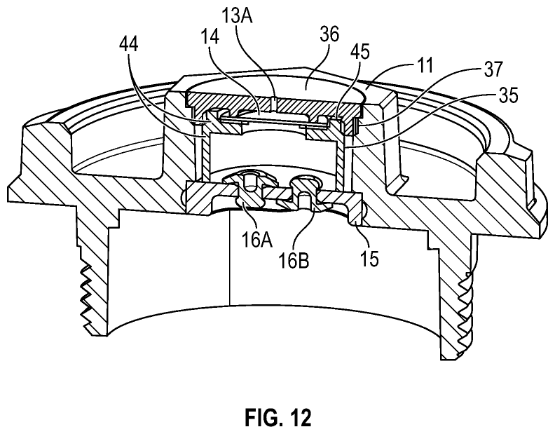

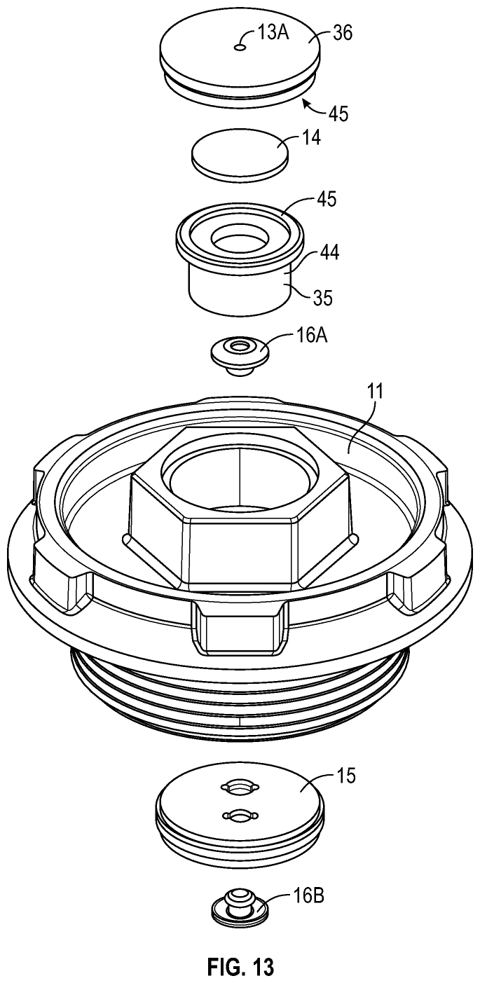

FIGS. 12-13 show a form of the cover assembly 10 where the insert 15 includes a support 35 and the cap 11 has a lid 36 that includes the at least one opening 13A. The lid 36 is ultrasonically welded to a recess 37 (see FIG. 12) in the cap 11 in the illustrated form. Although the lid 36 and the recess 37 are shown as being cylindrical, the overall size and shape of the lid 36 and the corresponding recess 37 will mostly depend on the configuration of the cap 11.

Other forms of attachment for the lid 36 to the cap 11 are contemplated (e.g., ssnp-fit). The lid 36 may be made from a variety of materials including, but not limited to, thermoplastic materials, especially thermoplastics that promote ultrasonic welding.

The support 35 in the cover assembly 10 engages an upper surface 44 of the insert 15 and a lower surface 45 of the lid 36. Even though the support 35 is shown as being cylindrical, it should be noted that other configurations are possible as long as air is allowed to flow back and forth into the enclosure 12 through the inlet valve 16A and the outlet valve 16B. The support 35 may be made from a variety of materials including, but not limited to, thermoplastic materials, especially thermoplastics that promote ultrasonic welding.

To better illustrate the cover assemblies 10 and/or the heads-up displays 1 disclosed herein, a non-limiting list of examples is provided here:

Example 1 is a cover assembly 10 comprising a cap 11 that seals an enclosure 12 and includes at least opening 13A to permit air to flow into and out of the enclosure 12; a membrane 14 that prevents water from entering the enclosure 12 through the at least one opening 13A in the cap 11 while permitting air to enter and exit the enclosure 12 through the at least one opening 13A in the cap 11: van insert 15 secured to the cap 11, wherein the membrane 14 is between the insert 15 and cap 11; andva valve 16A, 16B secured to the insert 15, the valve 16A, 16B allowing air to flow into and out of the enclosure 12.

Example 2 includes the cover assembly of example 1, wherein the membrane 14 is a hydrophobic membrane.

Example 3 includes the cover assembly of any one of examples 1-2, wherein the valve 16A, 16B includes an inlet valve 16A secured to the insert 15 and an outlet valve 16B secured to the insert 15 such that the inlet valve 16A allows air to flow into the enclosure 12 and the outlet valve 16B allows air to flow out of the enclosure 12.

Example 4 includes the cover assembly of example 3, wherein the inlet valve 16A and the outlet valve 16B are umbrella valves.

Example 5 includes the cover assembly of any one of examples 3-4, further comprising a shield 17 that protects the inlet valve 16A and the outlet valve 16B.

Example 6 includes the cover assembly of examples 1-5, further comprising a compressible spacer 19 that is compressed between the insert 15 and the membrane 14.

Example 7 includes the cover assembly of any one of examples 1-6, and further comprising a protective spacer 18 that is between the compressible spacer 19 and the insert 15.

Example 8 includes the cover assembly of any one of examples 1-7, further comprising a barrier 20 attached to the cap 11 to prevent particulates from entering the cover assembly 10 through the at least one opening 13A.

Example 9 includes the cover assembly of any one of examples 1-8, wherein the at least one opening 13A is three openings 13A, 13B, 13C.

Example 10 includes the cover assembly of example 9, wherein each of the three openings 13A, 13B, 13C has an elliptical diameter.

Example 11 includes the cover assembly of any one of examples 3-10, further comprising a gasket 21 between the insert 15 and the cap 11 to seal the insert 14 and the cap 11 to one another so that air only passes back and forth into the enclosure 12 through the at least one opening 13A in the cap 11.

Example 12 includes the cover assembly of any one of examples 1-11, and wherein the cap 11 includes internal threads 30 that are secured to external threads 32 on the insert 15.

Example 13 includes the cover assembly of example 12, wherein the internal threads 30 on the cap 11 are on an exterior surface 31 of the cap 11, and the external threads 32 on the insert 15 are on an exterior surface 33 of the insert 15.

Example 14 includes the cover assembly of example 13, further comprising a gasket 21 between the insert 15 and the cap 11, the gasket 21 providing a seal between the insert 15 and the cap 11 so that air only passes back and forth into the enclosure 12 through the at least one opening 13A in the cap 11, wherein the gasket 21 engages the exterior surface 33 of the insert 15 and the interior surface 31 of the cap 11 at a location adjacent to where the internal threads 30 on the cap 11 engage the external threads 32 on the insert 15.

Example 15 includes the cover assembly of any one of examples 3-14, wherein the insert 15 further includes a support 35 and the cap 11 includes a lid 36 that includes the at least one opening 13A.

Example 16 includes the cover assembly of example 15, wherein the lid 36 is ultrasonically welded to a recess 37 in the cap 11.

Example 17 includes the cover assembly of anyone of examples 15-16, wherein support 35 engages an upper surface 44 of the insert 15 and a lower surface 45 of the lid 36.

Example 18 is a heads-up display 1 configured to be worn on a user's head. The heads-up display 1 comprising an enclosure 12 that includes electronics to operate the heads-up display 1: a visor 2 attached to the enclosure 12, the visor 2 configured to engage the user's face: a screen 3 attached to the visor 2 and the enclosure 12 for displaying information to the user: and a cover assembly 10 that is secured to the enclosure 12, the cover assembly including: a cap 11 that seals the enclosure 12 and includes at least opening 13A to permit air to flow into and out of the enclosure 12: a hydrophobic membrane 14 that prevents moisture from entering the enclosure 12 through the at least one opening 13A in the cap 11 while permitting air to enter and exit the enclosure 12 through the at least one opening 13A in the cap 11: an insert 15 secured to the cap 11: and a valve 16A, 16B secured to the insert 15, the valve 16A, 16B allowing air to flow into the enclosure 12 and flow out of the enclosure 12, wherein the valve 16A, 16B includes an inlet valve 16A secured to the insert 15 and an outlet valve 16B secured to the insert 15 such that the inlet valve 16A allows air to flow into the enclosure 12 and the outlet valve 16B allows air to flow out of the enclosure 12.

Example 19 includes the heads-up display of example 18, further comprising an adjustable strap 4 that is attached to enclosure 12 and the visor 2 to facilitate securing the heads-up display 1 to the user's head.

Example 20 includes the heads-up display of any one of examples 18-19, wherein the inlet valve 16A and the outlet valve 16B are umbrella valves.

These and other examples and features of the heads-up displays and cover assemblies are set forth in part in the detailed description.

This overview is intended to provide non-limiting examples of the present subject matter. It is not intended to provide an exclusive or exhaustive explanation. The detailed description is included to provide further information about the heads-up displays 1 and cover assemblies 10 described herein.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description.

The Abstract is provided to comply with 37 C.F.R. § 1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A cover assembly comprising:
a cap that seals an enclosure and includes at least opening to permit air to flow into and out of the enclosure;
a membrane that prevents water from entering the enclosure through the at least one opening in the cap while permitting air to enter and exit the enclosure through the at least one opening in the cap;
an insert secured to the cap, wherein the membrane is between the insert and cap; and
a valve secured to the insert, the valve allowing air to flow into and out of the enclosure.

2. The cover assembly of claim 1, wherein the membrane is a hydrophobic membrane.

3. The cover assembly of claim 1, wherein the valve includes an inlet valve secured to the insert and an outlet valve secured to the insert such that the inlet valve allows air to flow into the enclosure and the outlet valve allows air to flow out of the enclosure.

4. The cover assembly of claim 3, wherein the inlet valve and the outlet valve are umbrella valves.

5. The cover assembly of claim 3, further comprising a shield that protects the inlet valve and the outlet valve.

6. The cover assembly of claim 1, further comprising a compressible spacer that is compressed between the insert and the membrane.

7. The cover assembly of claim 6, further comprising a protective spacer that is between the compressible spacer and the insert.

8. The cover assembly of claim 1, further comprising a barrier attached to the cap to prevent particulates from entering the cover assembly through the at least one opening.

9. The cover assembly of claim 1, wherein the at least one opening is three openings.

10. The cover assembly of claim 9, wherein each of the three openings has an elliptical diameter.

11. The cover assembly of claim 3, further comprising a gasket between the insert and the cap to seal the insert and the cap to one another so that air only passes back and forth into the enclosure through the at least one opening in the cap.

12. The cover assembly of claim 1, wherein the cap includes internal threads that are secured to external threads on the insert.

13. The cover assembly of claim 12, wherein the internal threads on the cap are on an exterior surface of the cap, and the external threads on the insert are on an exterior surface of the insert.

14. The cover assembly of claim 13, further comprising a gasket between the insert and the cap, the gasket providing a seal between the insert and the cap so that air only passes back and forth into the enclosure through the at least one opening in the cap, wherein the gasket engages the exterior surface of the insert and the interior surface of the cap at a location adjacent to where the internal threads on the cap engage the external threads on the insert.

15. The cover assembly of claim 3, wherein the insert further includes a support and the cap includes a lid that includes the at least one opening.

16. The cover assembly of claim 15, wherein the lid is ultrasonically welded to a recess in the cap.

17. The cover assembly of claim 15, wherein support engages an upper surface of the insert and a lower surface of the lid.

18. A heads-up display configured to be worn on a user's head, the heads-up display comprising:
an enclosure that includes electronics to operate the heads-up display;
a visor attached to the enclosure, the visor configured to engage the user's face;
a screen attached to the visor and the enclosure for displaying information to the user; and
a cover assembly that is secured to the enclosure, the cover assembly including:
a cap that seals the enclosure and includes at least opening to permit air to flow into and out of the enclosure;
a hydrophobic membrane that prevents moisture from entering the enclosure through the at least one opening in the cap while permitting air to enter and exit the enclosure through the at least one opening in the cap;
an insert secured to the cap; and
a valve secured to the insert, the valve allowing air to flow into the enclosure and flow out of the enclosure, wherein the valve includes an inlet valve secured to the insert and an outlet valve secured to the insert such that the inlet valve allows air to flow into the enclosure and the outlet valve allows air to flow out of the enclosure.

19. The heads-up display of claim 18, further comprising an adjustable strap that is attached to enclosure and the visor to facilitate securing the heads-up display to the user's head.

20. The heads-up display of claim 18, wherein the inlet valve and the outlet valve are umbrella valves.
